(19) United States
(12) Patent Application Publication
(10) Pub. No.: US 2025/0113434 A1
(43) Pub. Date: Apr. 3, 2025

(54) THROUGH GLASS VIA (TGV) WITH MODULATED PROFILE FOR CORE STRESS REDUCTION

(71) Applicant: Intel Corporation, Santa Clara, CA (US)

(72) Inventors: Bai NIE, Chandler, AZ (US); Mitchell PAGE, Mesa, AZ (US); Junxin WANG, Gilbert, AZ (US); Srinivas Venkata Ramanuja PIETAMBARAM, Chandler, AZ (US); Haifa HARIRI, Phoenix, AZ (US); Nicholas S. HAEHN, Scottsdale, AZ (US); Astitva TRIPATHI, Mesa, AZ (US); Yuqin LI, Chandler, AZ (US); Hongxia FENG, Chandler, AZ (US); Haobo CHEN, Chandler, AZ (US); Bohan SHAN, Chandler, AZ (US); Hiroki TANAKA, Gilbert, AZ (US); Leonel R. ARANA, Phoenix, AZ (US); Yonggang Yong LI, Chandler, AZ (US)

(21) Appl. No.: 18/374,617

(22) Filed: Sep. 28, 2023

(51) Int. Cl. H05K 1/02; H01L 23/15; H01L 23/498; H05K 1/03; H05K 1/11

(52) U.S. Cl. CPC H05K 1/0271; H01L 23/15; H01L 23/49827; H01L 23/49894; H05K 1/0306; H05K 1/116

(57) ABSTRACT

Embodiments disclosed herein include package substrates with a glass core. In an embodiment, an apparatus comprises a substrate with a first surface and a second surface opposite from the first surface, and the substrate is a solid glass layer. In an embodiment, an opening is provided through a thickness of the substrate, where the opening comprises a sidewall that is non-orthogonal with the first surface of the substrate. In an embodiment a corner at a junction between the sidewall and the first surface is rounded. In an embodiment, a via is provided in the opening, where the via is electrically conductive.

### BACKGROUND

As semiconductor packaging architectures continue towards more complex and more compact systems, new material solutions may be used to enable such architectures. One promising candidate for use in packaging substrates is a glass core layer. In such substrates, a glass core is sandwiched between overlying and underlying buildup layers. Electrically conductive vias are provided through the glass core in order to provide electrical coupling between the overlying and underlying buildup layers. Glass cores are beneficial because they can provide high density vias. Glass is also a high modulus material, which provides desirable stiffness to the overall package substrate.

However, glass cores are highly susceptible to fracture due to the combination of residual stresses and loading conditions that exceed the fracture strength of the glass core. For example, high temperature operations, (e.g., annealing processes, dielectric curing processes, and the like), can result in via copper delamination or glass cracking. These stresses are mainly attributable to a coefficient of thermal expansion (CTE) mismatch between the glass core and the via (e.g., copper). The geometry of the vias may also play a role in the stress generation. For example, sharp corners of via architectures can result in high localized stresses that lead to glass fracture.

### BRIEF DESCRIPTION OF THE DRAWINGS

FIG. 1 is a cross-sectional illustration of a glass core that includes a via with sharp corners and voids, in accordance with an embodiment.

FIG. 2A is a cross-sectional illustration of a glass core that includes a via that is formed with rounded corners in order to reduce stress concentrations, in accordance with an embodiment.

FIG. 2B is a cross-sectional illustration of a glass core that includes a liner with a vertical interior surface that allows for a via with vertical sidewalls, in accordance with an embodiment.

FIG. 2C is a cross-sectional illustration of a glass core that includes a liner over bumps at the top and bottom of the via opening, in accordance with an embodiment.

FIG. 2D is a cross-sectional illustration of a glass core that includes a via with a four-segment sidewall, in accordance with an embodiment.

FIG. 2E is a cross-sectional illustration of a glass core that includes a via with a four-segment sidewall and a pad over the via, in accordance with an embodiment.

FIGS. 3A-3D are cross-sectional illustration depicting a process for forming vias in a glass core with rounded corners, in accordance with an embodiment.

FIGS. 4A-4D are cross-sectional illustrations depicting a process for forming a via in a glass core that is surrounded by a liner with a variable thickness, in accordance with an embodiment.

FIGS. 5A-5D are cross-sectional illustrations depicting a process for forming a via in a glass core that is surrounded by a liner that is provided over bumps at the top and bottom of the via, in accordance with an embodiment.

FIGS. 6A-6I are cross-sectional illustrations depicting a process for forming a via through a glass core that includes a four-segment sidewall, in accordance with an embodiment.

FIG. 7 is a cross-sectional illustration of a package substrate that includes a glass core with a via with stress reducing geometry, in accordance with an embodiment.

FIG. 8 is a cross-sectional illustration of an electronic system that includes a package substrate with a glass core and vias that include stress reducing geometries, in accordance with an embodiment.

FIG. 9 is a schematic of a computing device built in accordance with an embodiment.

### EMBODIMENTS OF THE PRESENT DISCLOSURE

Described herein are electronic systems, and more particularly, glass cores with through glass vias (TGVs) that include modified profiles for stress reduction, in accordance with various embodiments. In the following description, various aspects of the illustrative implementations will be described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials and configurations are set forth in order to provide a thorough understanding of the illustrative implementations. However, it will be apparent to one skilled in the art that the present disclosure may be practiced without the specific details. In other instances, well-known features are omitted or simplified in order not to obscure the illustrative implementations.

Various operations will be described as multiple discrete operations, in turn, in a manner that is most helpful in understanding the present disclosure, however, the order of description should not be construed to imply that these operations are necessarily order dependent. In particular, these operations need not be performed in the order of presentation.

As noted above, coefficient of thermal expansion (CTE) mismatches between glass cores and the through glass vias (TGVs) that pass through the glass cores can result in significant damage. For example, delamination defects or complete device failure due to cracking or the like may occur. In addition to CTE mismatch, existing TGV manufacturing process provide sharp interfaces or corners. These points result in significant stress concentrations and can increase the probability of glass fracturing or delamination.

In order to meet the necessary size, pitch, and aspect ratio requirements for advanced packaging solutions, TGVs (also referred to simply as “vias” herein) are often fabricated with a laser assisted etching process. Laser assisted etching includes exposing the glass material to a laser. The laser modifies the structure of the glass and makes the glass more susceptible to an etching solution (which is typically a wet etching chemistry). Following the etching process, an opening through the glass is provided. Laser assisted etching processes are generally characterized as having opening sidewalls that are tapered. In a double sided exposure process (i.e., when lasers are used to expose both the top and bottom surface of the glass core), the sidewalls will have a double tapered structure. That is, the opening may have an hourglass like shape with a narrow middle portion and wider top and bottom portions.

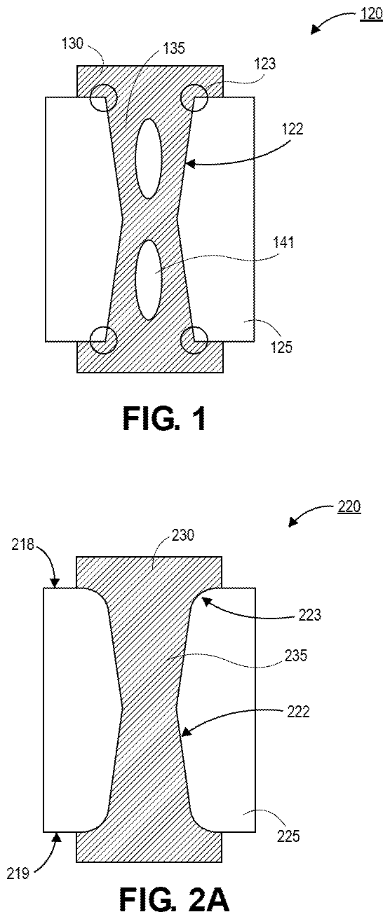

However, such laser assisted etching processes are not as controllable as desired. For example, corners where the sidewalls of the openings meet the top or bottom surfaces will be relatively sharp or pointed. This can lead to additional stress concentrations which, as described above, can contribute to device failures. An example of such a structure is shown in FIG. 1.

As shown, the glass core 120 includes a glass layer 125. A via 135 is provided through a thickness of the glass layer 125. For example, the via 135 may be formed with a laser assisted etching process, such as described above. Accordingly, the sidewalls 122 may be sloped or otherwise tapered. Pads 130 may be provided above and/or below the via 135. Due to the high aspect ratio and the sloping sidewalls 122, the via 135 may be difficult to fill, and voids 141 may be present. Voids increase the resistance along the via 135 and electrical performance is negatively impacted.

Additionally, the corners 123 at the top and bottom of the via 135 are sharp with substantially no rounding. As such, stress concentrations are formed and the probability of cracking in the glass is increased. In contrast, rounded corners 123 would enable stress reduction. A solution for providing rounded corners includes the use of an electrical discharge process in order to form the via opening. Such processes allow for rounded corners 123 due to glass melting effects. However, electrical discharge processes are not compatible with advanced packaging solutions where via 135 aspect ratios (height:width) are 10:1 or greater. Further, fillet radius is poorly controlled with such processes, and repeatability is limited. Electrical discharge processes are also slow compared to laser assisted etch processes. For example, electrical discharge can produce several vias per second while laser assisted etch can produce hundreds or more of vias per second. Via 135 taper is also easier to control with laser assisted processes.

Accordingly, embodiments disclosed herein provide several different approaches to limit the stress concentrations at the corners of the via openings. In one embodiment, a laser exposure process is a two operation process. A first operation includes a traditional laser exposure, and a second operation includes an ultrafast laser inscription (ULI) process. The ULI process treats the corner regions and can enable profile control that includes the formation of rounded corners.

In another embodiment, a liner is provided along sidewalls of the via opening. However, instead of a liner with surfaces that match the profile of the sidewalls of the via opening, the inner surface of the liner (that interfaces with the via) is substantially vertical. This results in a liner that is thicker at the top and bottom compared to a thinner middle region. The thicker portions at the top and bottom (near the corners) helps reduce the stress concentration at the corners. Non-uniform thickness liners allow for a higher volumes of liner material only where needed. This allows for higher volumes of electrically conductive via material compared to traditional liner approaches. As such, electrical performance can be improved.

In an additional embodiment, a via with a four-segment sidewall is provided. The middle segments are similar to a typical laser assisted etching via opening profile. The outer segments (that connect to the top and bottom surface of the core) will have a shallower taper. The shallower taper allows for a reduction in stress. The variable taper solution may be obtained through the use of first and second laser assisted etching processes.

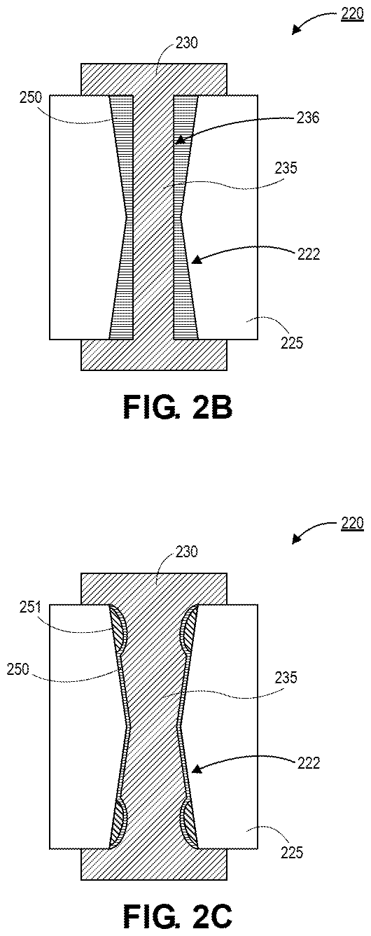

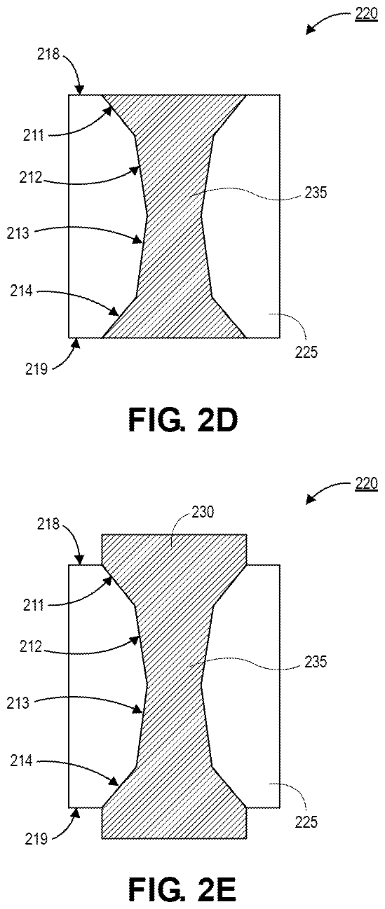

Referring now to FIG. 2A, a cross-sectional illustration of a glass core 220 is shown, in accordance with an embodiment. The glass core 220 comprises a glass layer 225. The glass layer 225 may be substantially all glass. The glass layer 225 may be a solid material with an amorphous crystal structure. More particularly, the glass layer 225 may be any suitable glass formulation that has the necessary mechanical robustness and compatibility with semiconductor packaging manufacturing and assembly processes. For example, the glass layer 225 may comprise aluminosilicate glass, borosilicate glass, alumino-borosilicate glass, silica, fused silica, or the like. In some embodiments, the glass layer 225 may include one or more additives, such as, but not limited to, Al₂O₃, B₂O₃, MgO, CaO, SrO, BaO, SnO₂, Na₂O, K₂O, SrO, P₂O₃, ZrO₂, Li₂O, Ti, and Zn. More generally, the glass layer 225 may comprise silicon and oxygen, as well as any one or more of aluminum, boron, magnesium, calcium, barium, tin, sodium, potassium, strontium, phosphorus, zirconium, lithium, titanium, and zinc. In an embodiment, the glass layer 225 may comprise at least 23 percent silicon (by weight) and at least 26 percent oxygen (by weight). In some embodiments, the glass layer 225 may further comprise at least 5 percent aluminum (by weight).

In an embodiment, the glass layer 225 may have a rectangular shape when viewed from above in a plan view. Though, the glass layer 225 may also have other shapes. In an embodiment, the glass layer 225 may have a thickness between approximately 50 μm and approximately 2,000 μm. Though, thinner or thicker glass layers 225 may also be used in some embodiments. As used herein, “approximately” may refer to a range of values within ten percent of the stated value. For example approximately 100 μm may refer to a range between 90 μm and 110 μm.

In an embodiment, a via 235 may be provided through a thickness of the glass layer 225 between a top surface 218 and a bottom surface 219. The via 235 may be disposed in an opening that is defined by sidewalls 222. The sidewalls 222 may be sloped or tapered. In some embodiments, the via 235 may have an hourglass shaped cross section. In other embodiments, the via 235 may have a single taper. That is, the via 235 proximate to the top surface 218 may be wider than the via 235 proximate to the bottom surface 219. In an embodiment, the via 235 may be a high aspect ratio feature. As used herein, a “high aspect ratio” feature may include an aspect ratio (height:width) that is approximately 5:1 or greater, approximately 10:1 or greater, or approximately 20:1 or greater. In some embodiments, a maximum width of the via 235 may be up to approximately 100 μm.

In an embodiment, the via 235 is an electrically conductive material. The via 235 may comprise copper, an alloy of copper, or any other electrically conductive metallic material. In the illustrated embodiment, the via 235 directly contacts the sidewalls 222. However, embodiments may also include a seed layer (not shown) or any other suitable layer between the via 235 and the sidewalls 222. A seed layer may be useful for allowing for electroplating of the via 235. In other embodiments disclosed herein, the seed layer may be similarly omitted. However, it is to be appreciated that vias described herein may optionally include a seed layer, even when not shown or described. In an embodiment, pads 230 may be provided above and/or below the via 235. The pads 230 may be wider than the via 235, the pads 230 may be substantially the same width as the via 235, or the pads 230 may be narrower than the via 235.

In an embodiment, the sidewalls 222 of the via opening meet with the top surface 218 and the bottom surface 219 at corners 223. As shown, the corners 223 are rounded. In an embodiment, the corners 223 may have a radius of curvature (or fillet radius) that is up to approximately 50 μm. For example, the corners 223 may have a radius of curvature that is between approximately 0.1 μm and approximately 3 μm. Fine tuning of the radius of curvature for the corners 223 is made possible through the use of an ultrafast laser inscription (ULI) process that is used in addition to standard laser assisted etching. The processing will be described in greater detail below.

Referring now to FIG. 2B, a cross-sectional illustration of a glass core 220 is shown, in accordance with an additional embodiment. In an embodiment, the glass core 220 comprises a glass layer 225, similar to the embodiment described in FIG. 2A. The via opening may have tapered sidewalls 222. However, instead of providing the via 235 directly over the sidewalls 222, the via 235 in FIG. 2B is separated from the glass layer 225 by a liner 250.

In an embodiment, the liner 250 may have an elastic modulus that is lower than the elastic modulus of the via 235. The lower modulus of the liner 250 allows for the liner 250 to elastically deform during expansion of the via 235, and stress is absorbed by the liner 250 instead of being applied to the glass layer 225. In some embodiments, the liner 250 is electrically insulating (e.g., a polymer) or is less electrically conductive than the via 235 (e.g., aluminum). Accordingly, increasing the volume of the liner 250 within the via opening can have negative electrical performance impacts.

As such, the liner 250 may have a higher thickness in areas where stresses are high and lower thicknesses in areas where stresses are low. For example, the top and bottom of the liner 250 may be thicker than a middle of the liner 250. This provides protection to the high stress concentration regions at the corners of the via 235. The top and bottom of the liner 250 may have a thickness that is up to approximately 30 μm, and the middle of the liner 250 may have a thickness that is up to approximately 10 μm. Though, thicker or thinner liner 250 portions may also be used in some embodiments.

In an embodiment, the outer surface of the liner 250 may conform to the sidewalls 222 of the via opening, and the inner surface 236 of the liner 250 may be substantially vertical (e.g., substantially orthogonal to the top and bottom surface of the glass layer 225). Since the inner surface 236 is substantially vertical, the via 235 may have a rectangular shaped cross-section as opposed to an hourglass shaped cross-section. As used herein, “substantially orthogonal” may refer to two surfaces that are within approximately 10° of being orthogonal with each other.

Referring now to FIG. 2C, a glass core 220 in accordance with an additional embodiment is shown, in accordance with an embodiment. The embodiment shown in FIG. 2C relies on a similar concept as the glass core 220 in FIG. 2B. That is, thicker liners 250 are provided near the top and bottom of the via 235 in order to mitigate high stress regions. However, instead of a liner structure with a single layer, the liner structure in FIG. 2C includes a dual layer approach.

A first portion of the liner structure is a bump 251 that is provided towards the top and bottom of the via opening. The bump 251 may be a low modulus material (compared to the via 235). The bump 251 provides protection to the corners of the via opening. In the illustrated embodiment, the bumps 251 have a flat surface against the sidewalls 222 and a rounded surface facing away from the sidewalls 222. The bumps 251 may be described as being semi-elliptical structures. However, other shapes may also be used for the bumps 251 in some embodiments.

The second portion of the liner structure is a liner 250. The liner 250 may also be a low modulus material. In some embodiments, the liner 250 and the bump 251 are different materials. In other embodiments, the liner 250 and the bump 251 are the same material. The liner 250 may cover the bump 251 and the exposed sidewalls 222 of the via opening. The liner 250 may have a uniform thickness. For example, the liner 250 may have a thickness between approximately lum and approximately 10 μm.

The combined shape of the liner structure may result in a unique cross-sectional shape for the via 235. For example, portions of the via 235 proximate to the top and bottom may have a concave surface, an indentation, a cavity, or the like. Proximate to the middle of the via 235, the via 235 may have linear sidewalls that taper inwards. That is, both curved and linear sidewalls may be present along a single via 235 structure in some embodiments.

Referring now to FIG. 2D, a cross-sectional illustration of a glass core 220 is shown, in accordance with an additional embodiment. In the embodiment shown in FIG. 2D, the via 235 may be described as having a multi-segment (e.g., a four-segment) sidewall structure. The inner sidewalls 212 and 213 may have a steeper slope than the outer sidewalls 211 and 214. The shallower slope of the outer sidewalls 211 and 214 provides a less aggressive corner at the interface with the top surface 218 or bottom surface 219 of the glass layer 225. Accordingly, stress induced into the glass layer 225 can be reduced. In some embodiments, a double laser assisted etching process is used to form such a structure, as will be described in greater detail below.

In an embodiment, four segments (211-214) are shown. Other embodiments may include more than four segments. The segments 211 and 212 may be mirror images of the segments 213 and 214. That is, the angle of segment 211 relative to the top surface 218 may be substantially equal to the angle of segment 214 relative to the bottom surface 219, and the angle of segment 212 relative to the top surface 218 may be substantially equal to the angle of segment 213 relative to the bottom surface 219. In an embodiment, the inner segments 212 and 213 may be longer than the outer segments 211 and 214.

Referring now to FIG. 2E, a cross-sectional illustration of a glass core 220 is shown, in accordance with an additional embodiment. As shown, the glass core 220 in FIG. 2E is substantially similar to the glass core 220 in FIG. 2D, with the exception of the inclusion of pads 230 over and under the via 235. The pads 230 may be formed during a plating process used to form the via 235. The pads 230 may have a width that is substantially equal to a maximum width of the via 235. For example, the edges of the pads 230 may be substantially aligned with edges of the via 235. Such an embodiment may be obtained using a resist layer with an opening aligned over the via opening, during plating, as will be described in greater detail below.

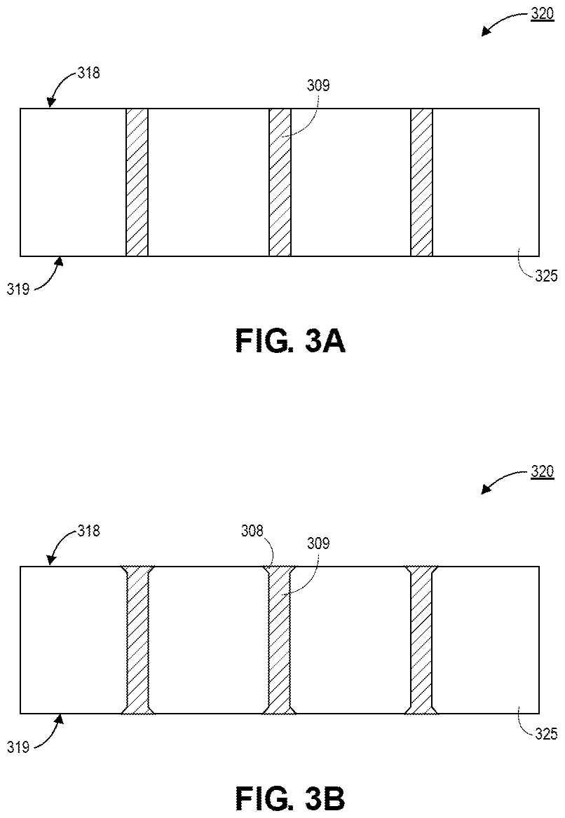

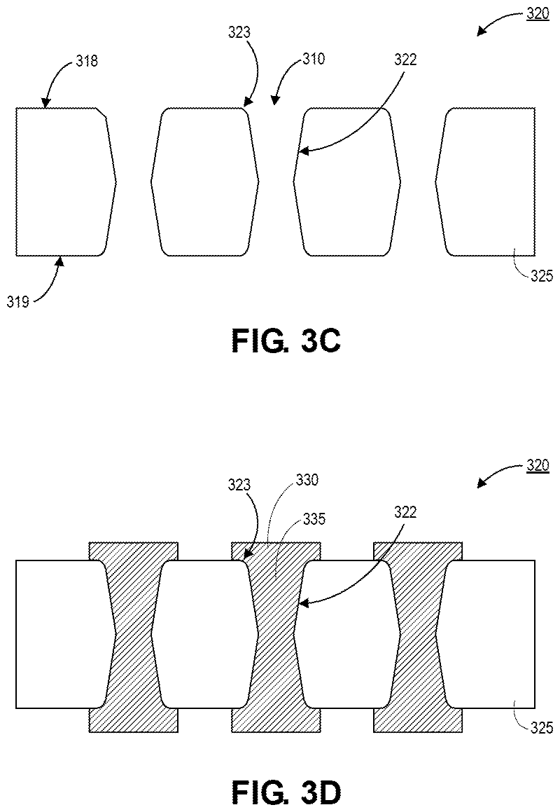

Referring now to FIGS. 3A-3D a series of cross-sectional illustrations depicting a process for forming a glass core 320 is shown, in accordance with an embodiment. In an embodiment, the glass core 320 includes via openings 310 that include rounded corners 323, similar to the embodiment shown in FIG. 2A.

Referring now to FIG. 3A, a cross-sectional illustration of a glass core 320 is shown, in accordance with an embodiment. In an embodiment, the glass core 320 comprises a glass layer 325. The glass layer 325 may be similar in composition and geometry to any of the glass layers described in greater detail herein. In an embodiment, the glass layer 325 is exposed with a laser (e.g., with a Bessel beam) in order to form exposed regions 309. The exposed regions 309 may have a modified structure compared to the rest of the glass layer 325. The modified structure makes the exposed regions 309 more susceptible to an etching process. In some embodiments, the laser exposure is a single sided exposure. In other embodiments, the laser exposure is a double sided exposure. That is, the laser may expose the top surface 318 and/or the bottom surface 319.

Referring now to FIG. 3B, a cross-sectional illustration of the glass core 320 after a second exposure process is shown, in accordance with an embodiment. In an embodiment, the second exposure process results in the formation of regions 308 at the top and bottom of the glass layer 320 on opposite ends of the exposed regions 309. The second exposure process may include the use of an ultrafast laser inscription (ULI) process. ULI processes can achieve up to approximately lum level accuracy in terms of position and feature size.

Referring now to FIG. 3C, a cross-sectional illustration of the glass core 320 after an etching process is used to form via openings 310 in the glass layer 325 is shown, in accordance with an embodiment. The etching process may be a wet etching process in some embodiments. The regions 308 and 309 are more susceptible to the etching chemistry and will be preferentially etched relative to the rest of the glass layer 325.

In an embodiment, the via opening 310 may have sidewalls 322. The sidewalls 322 may be sloped or otherwise tapered. For example, the sidewalls 322 may result in a via opening 310 that includes an hourglass shaped cross-sectional shape. Though, other shaped sidewall 322 profiles may also be obtained in some embodiments. In an embodiment, the regions 308 may also result in the generation of curved corners 323 where the sidewalls 322 meet the top surface 318 and the bottom surface 319. A radius of curvature of the corners 323 may be up to approximately 50 μm. For example, the radius of curvature of the corners 323 may be between approximately 0.1 μm and approximately 3 μm in some embodiments. The use of curved corners 323 provides a reduction in stress concentration at the corners 323 during high temperature processes, such as annealing and the like.

Referring now to FIG. 3D, a cross-sectional illustration of the glass core 320 after vias 335 and pads 330 are formed is shown, in accordance with an embodiment. In some instances, the vias 335 and pads 330 may be plated up using an electroplating process or the like. In such embodiments, a seed layer (not shown) may be provided between the vias 335 and the sidewalls 322.

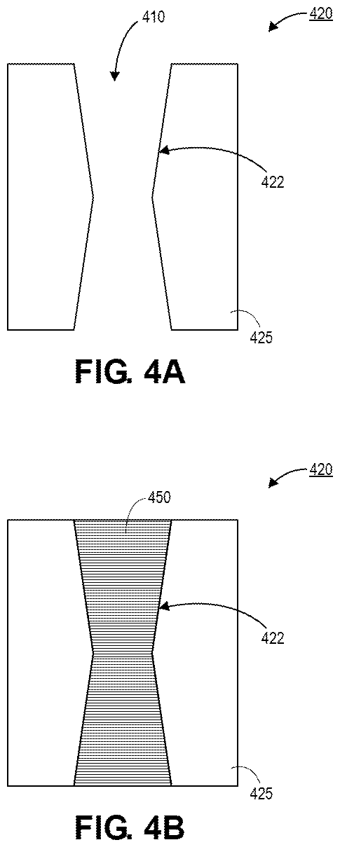

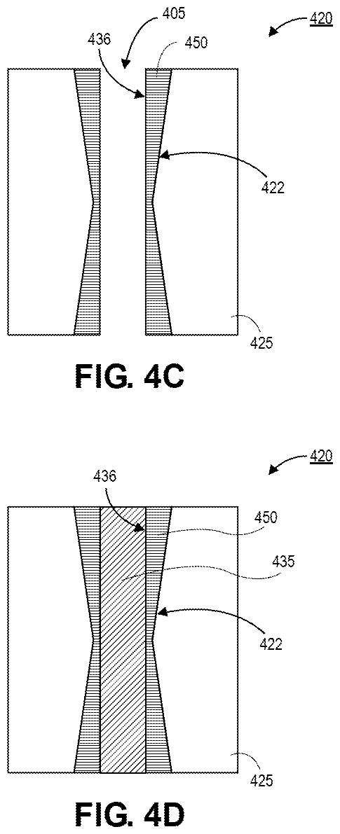

Referring now to FIGS. 4A-4D, a series of cross-sectional illustrations depicting a process for forming a glass core 420 is shown, in accordance with an embodiment. The glass core 420 may include a liner 450 with a non-uniform thickness. That is, the top and bottom of the liner 450 may be thicker than a middle of the liner 450 in order to mitigate stress at high stress concentration regions.

Referring now to FIG. 4A, a cross-sectional illustration of a glass core 420 is shown, in accordance with an embodiment. The glass core 420 may comprise a glass layer 425. The glass layer 425 may be similar to any of the glass layers described in greater detail herein. In an embodiment, a via opening 410 may be formed through a thickness of the glass layer 425. The via opening 410 may be formed with a laser assisted etching process or the like. The via opening 410 may include sidewalls 422. The sidewalls 422 may be tapered or otherwise sloped. For example, the via opening 410 in FIG. 4A may have an hourglass shaped cross-section in some embodiments. Though, via openings 410 with other cross-sectional shapes may also be provided in some embodiments.

Referring now to FIG. 4B, a cross-sectional illustration of the glass core 420 after a liner 450 is deposited in the via opening 410 is shown, in accordance with an embodiment. The liner 450 may be a low elastic modulus material (compared to copper). The liner 450 may be electrically non-conductive in some embodiments. For example, the liner 450 may comprise a polymer in some instances. The liner 450 may be deposited with any suitable process, such as chemical vapor deposition (CVD), physical vapor deposition (PVD), or the like.

Referring now to FIG. 4C, a cross-sectional illustration of the glass core 420 after an opening 405 is formed through the liner 450 is shown, in accordance with an embodiment. In an embodiment, the opening 405 may be formed with a mechanical process. For example, a drilling process may be used in order to form the opening 405. The resulting inner surface 436 of the liner 450 may be substantially vertical in some embodiments. That is, the inner surface 436 may be substantially orthogonal to a top or bottom surface of the glass layer 425.

In an embodiment, the resulting structure of the liner 450 includes a thickness that is non-uniform. For example, the regions proximate to the top and bottom of the glass layer 425 may be thicker than a region proximate to a middle of the glass layer 425. This enables efficient stress reduction at high stress areas (e.g., corners of the via opening 410) while minimizing volume occupied by the liner 450. As such, electrical performance (e.g., Imax) is maintained as high as possible, and scalability to smaller via dimensions and pitches is retained.

Referring now to FIG. 4D, a cross-sectional illustration of the glass core 420 after the via 435 is deposited is shown, in accordance with an embodiment. The via 435 may be deposited with an electroplating process. In such embodiments, a seed layer (not shown) may be provided between the via 435 and the liner 450. Due to the profile of the inner surface 436 of the liner 450, the via 435 may have a substantially rectangular cross-sectional shape in some embodiments.

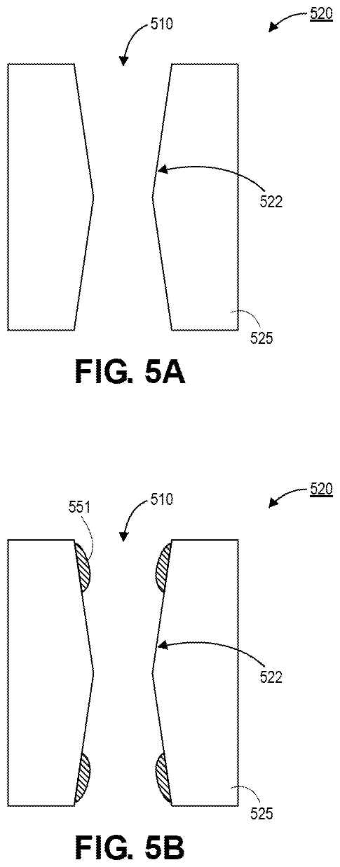

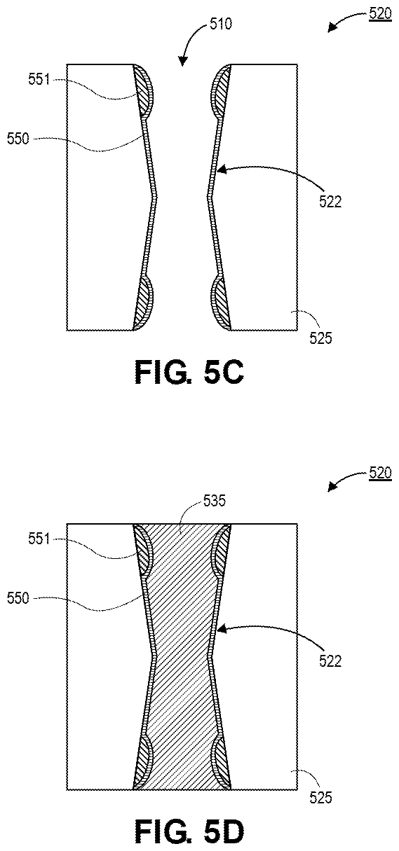

Referring now to FIGS. 5A-5D, a series of cross-sectional illustrations depicting a process for forming a glass core 520 is shown, in accordance with an embodiment. The glass core 520 may include a liner structure that includes a bump 551 and a liner 550. The bump 551 is provided at the top and bottom of the via opening 510, and the liner 550 covers the bumps 551 and sidewalls 522 of the via opening. Accordingly, a larger volume of stress reduction material is provided at high stress concentration regions while maximizing the volume of via 535 material.

Referring now to FIG. 5A, a cross-sectional illustration of a glass core 520 is shown, in accordance with an embodiment. The glass core 520 may comprise a glass layer 525. The glass layer 525 may be similar to any of the glass layers described in greater detail herein. In an embodiment, a via opening 510 may be formed through a thickness of the glass layer 525. The via opening 510 may be formed with a laser assisted etching process or the like. The via opening 510 may include sidewalls 522. The sidewalls 522 may be tapered or otherwise sloped. For example, the via opening 510 in FIG. 5A may have an hourglass shaped cross-section in some embodiments. Though, via openings 510 with other cross-sectional shapes may also be provided in some embodiments.

Referring now to FIG. 5B, a cross-sectional illustration of the glass core 520 after the bumps 551 are applied is shown, in accordance with an embodiment. In an embodiment, the bumps 551 may be a low elastic modulus material (compared to copper). For example, the bumps 551 may be a polymeric material or the like. The bumps 551 may be provided at the top and bottom of the via opening 510. In the cross-sectional view, four bumps 551 are shown. Though, it is to be appreciated that the bumps 551 may actually be a pair of rings (one at the top of the via opening 510 and one at the bottom of the via opening). In an embodiment, the bumps 551 have a semi-elliptical shape. Though, embodiments may include bumps 551 with any suitable shape. In an embodiment, the bumps 551 may be applied with a slit coating process or the like. Further, in some embodiments, a slit coating process may result in bumps 551 at the top and bottom that are connected together along the length of the sidewall 522. However, the regions at the top and the bottom will have a greater thickness than the remainder of the layer along the middle portion of the sidewall 522.

Referring now to FIG. 5C, a cross-sectional illustration of the glass core 520 after a liner 550 is applied is shown, in accordance with an embodiment. The liner 550 may also be a low modulus material (compared to copper). For example, the liner 550 may be a polymer. In some embodiments, the liner 550 and the bumps 551 are different materials. In other embodiments, the liner 550 and the bumps 551 are the same material. The liner conforms to the surface of the bumps 551 and sidewalls 522 of the via opening 510. As such, the liner 550 may have both a curved surface and a linear surface. The liner 550 may be applied with a CVD process or the like. In embodiments where the bumps 551 are continuous along the sidewalls 522, the liner 550 may be separated from the sidewall 522 by a portion of the bump 551 material. The liner 550 may have a uniform thickness through the length of the opening 510.

Referring now to FIG. 5D, a cross-sectional illustration of the glass core 520 after a via 535 is applied in the via opening 510 is shown, in accordance with an embodiment. In an embodiment, the via 535 may be deposited with an electroplating process. For example, a seed layer (not shown) may be applied over the liner 550, and the via 535 may be plated up from the seed layer.

Due to the profile of the liner structure, the via 535 may have a unique cross-sectional shape. For example, cavities or divots may be formed into top and bottom regions of the via 535. The middle portion of the via 535 may have linear sidewall portions as well. As such, the via 535 may have both curved sidewall portions and linear sidewall portions.

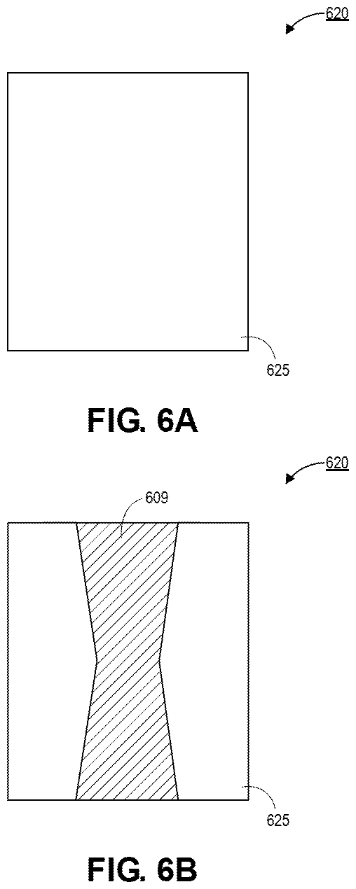

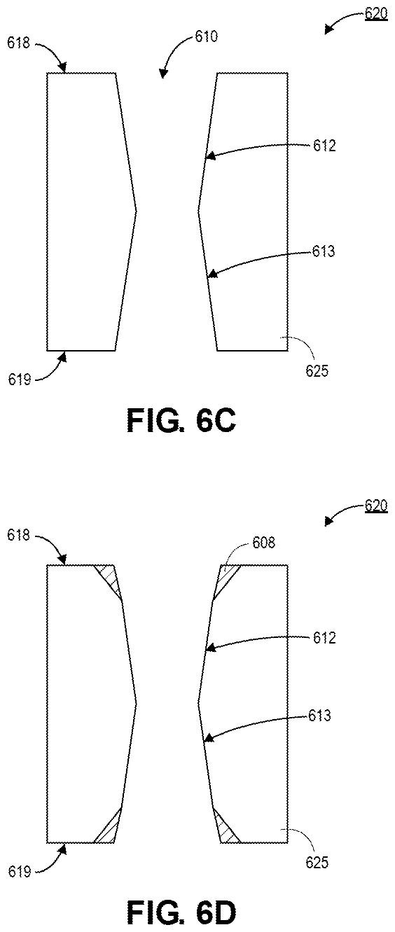

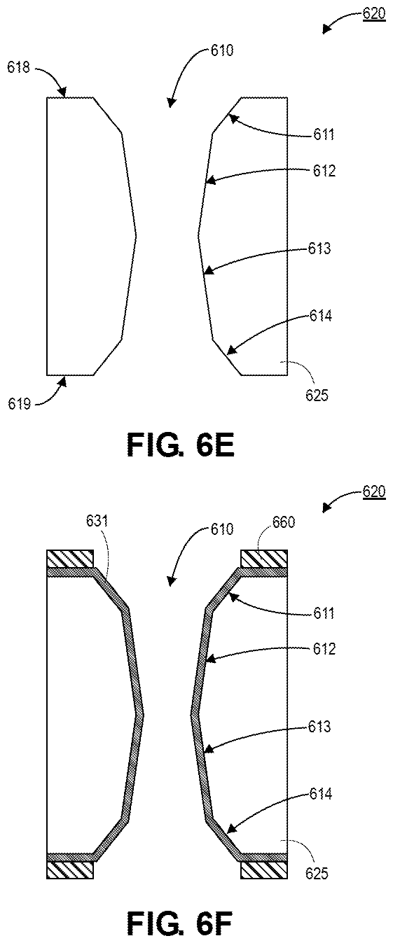

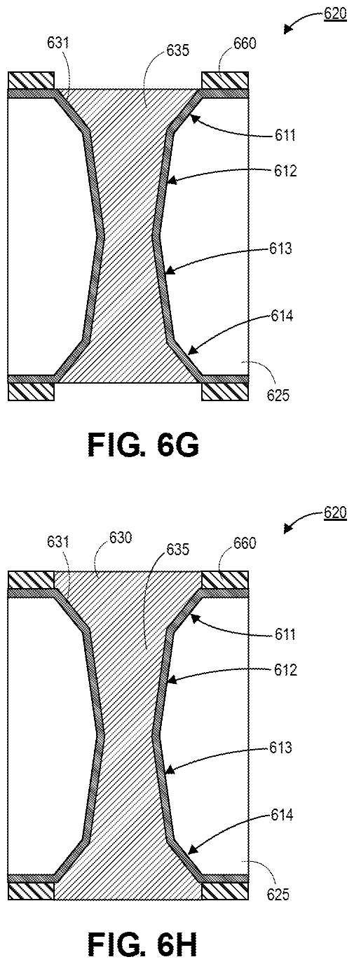

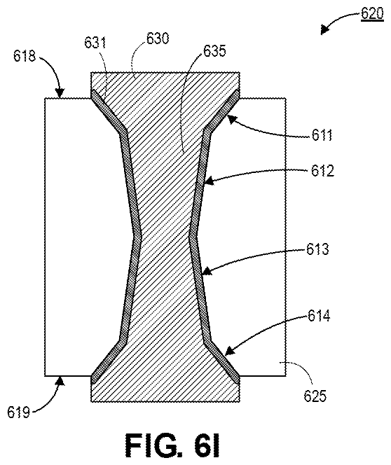

Referring now to FIGS. 6A-6I, a series of cross-sectional illustrations depicting a process for forming a glass core 620 with a via that includes a via 635 with a multi-segment sidewall is shown, in accordance with an embodiment. The multi-segment sidewall provides a less aggressive slope that interfaces with the top surface 618 and the bottom surface 619 of the glass layer 625. This reduces the stress concentration at the corners of the via 635.

Referring now to FIG. 6A, a cross-sectional illustration of a glass core 620 is shown, in accordance with an embodiment. The glass core 620 may comprise a glass layer 625. The glass layer 625 may be similar to any of the glass layers described in greater detail herein.

Referring now to FIG. 6B, a cross-sectional illustration of the glass core 620 after a first laser exposure to form exposed region 609 is shown, in accordance with an embodiment. In an embodiment, the exposed region 609 may have a microstructure that is more susceptible to an etching chemistry than the remainder of the glass layer 625.

Referring now to FIG. 6C, a cross-sectional illustration of the glass core 620 after a via opening 610 is formed through a thickness of the glass layer 625 between a top surface 618 and a bottom surface 619 is shown, in accordance with an embodiment. The via opening 610 may be formed with an etching process that selectively removes the exposed region 609. The via opening 610 may include sidewall segments 612 and 613. The sidewall segments 612 and 613 may be tapered or otherwise sloped. For example, the via opening 610 in FIG. 6C may have an hourglass shaped cross-section in some embodiments. Though, via openings 610 with other cross-sectional shapes may also be provided in some embodiments.

Referring now to FIG. 6D, a cross-sectional illustration of the glass core 620 after a second laser exposure is shown, in accordance with an embodiment. The second laser exposure may result in the formation of exposed regions 608 at the top and bottom of the glass layer 625. In an embodiment, the second laser exposure is shorter than the first laser exposure, and the second laser exposure has a spatially wider laser pulse.

Referring now to FIG. 6E, a cross-sectional illustration of the glass core 620 after a second etching process is shown, in accordance with an embodiment. In an embodiment, the second etching process preferentially removes the exposed regions 608 at the top and bottom of the glass layer 625. Accordingly, the resulting via opening 610 is left with sidewalls that have a multi-segment profile. For example, a first segment 611, a second segment 612, a third segment 613, and a fourth segment 614 are provided.

In an embodiment, the first segment 611 and the fourth segment 614 are mirror images of each other, and the second segment 612 and the third segment 613 are mirror images of each other. The first segment 611 may have a slope (relative to the top surface 618) that is shallower than a slope of the second segment 612 (relative to the top surface 618). This allows for a less severe corner at the top surface 618. Similarly, the fourth segment 614 has a smaller angle (relative to the bottom surface 619) compared to a slope of the third segment 613 (relative to the bottom surface 619). In an embodiment, the lengths of the inner segments (i.e., the second segment 612 and the third segment 613) may be longer than lengths of the outer segments (i.e., the first segment 611 and the fourth segment 614).

Referring now to FIG. 6F, a cross-sectional illustration of the glass core 620 after a seed layer 631 and a resist layer 660 is applied is shown, in accordance with an embodiment. In an embodiment, the seed layer 631 may be applied with an electroless plating process across the sidewalls of the via opening 610, the top surface 618, and the bottom surface 619. The resist layer 660 may be a dry film resist or the like. An opening in the resist layer 660 may be centered over the via opening 610.

Referring now to FIG. 6G, a cross-sectional illustration of the glass core 620 after a via 635 is formed is shown, in accordance with an embodiment. The via 635 may be plated up from the seed layer 631 using an electroplating process or the like. The resist layer 660 prevents copper from plating over the top surface 618 and the bottom surface 619. As shown in FIG. 6G, the plating may be halted before the via 635 extends beyond the top surface 618 and the bottom surface 619.

Referring now to FIG. 6H, a cross-sectional illustration of the glass core 620 with a via 635 is shown, in accordance with an alternative embodiment. Instead of halting the plating, the plating is allowed to continue past the top surface 618 and the bottom surface 619. This generates pads 630 above and below the via 635. As shown, the pads 630 may be substantially aligned with the underlying via 635. That is, edges of the via 635 may be substantially aligned with edges of the pads 630 in some embodiments.

Referring now to FIG. 6I, a cross-sectional illustration of the glass core 620 after the resist layer 660 and seed layer 631 is removed from the top surface 618 and the bottom surface 619 is shown, in accordance with an embodiment. The resist layer 660 may be removed with a resist stripping process or the like. The seed layer 631 may be removed with an etching process, such as a timed wet etch.

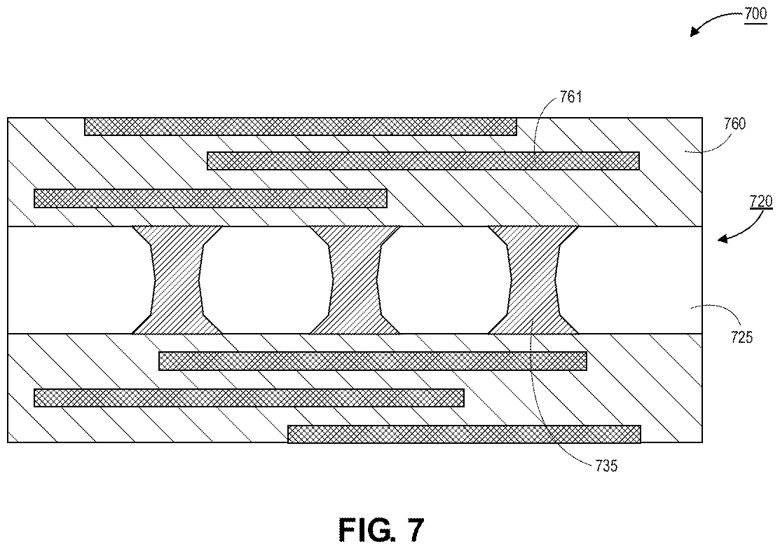

Referring now to FIG. 7, a cross-sectional illustration of a package substrate 700 is shown, in accordance with an embodiment. In an embodiment, the package substrate 700 comprises a glass core 720. The glass core 720 may include a glass layer 725 and a via 735 through a thickness of the glass layer 725. In an embodiment, the glass core 720 may be similar to any of the glass cores described in greater detail herein. The via 735 shown in FIG. 7 is a multi-segment via. Though, vias 725 with rounded corners, non-uniform thickness liners, multi-component liner structures, or combinations thereof may also be included in the glass core 720.

In an embodiment, buildup layers 760 may be provided above and/or below the glass core 720. The buildup layers 760 may comprise organic dielectric material. For example, laminated buildup film layers may be used to form the buildup layers 760. In an embodiment, electrically conductive features 761 (e.g., pads, vias, traces, etc.) may be embedded within the buildup layers 760 in order to provide electrical routing within the package substrate 700.

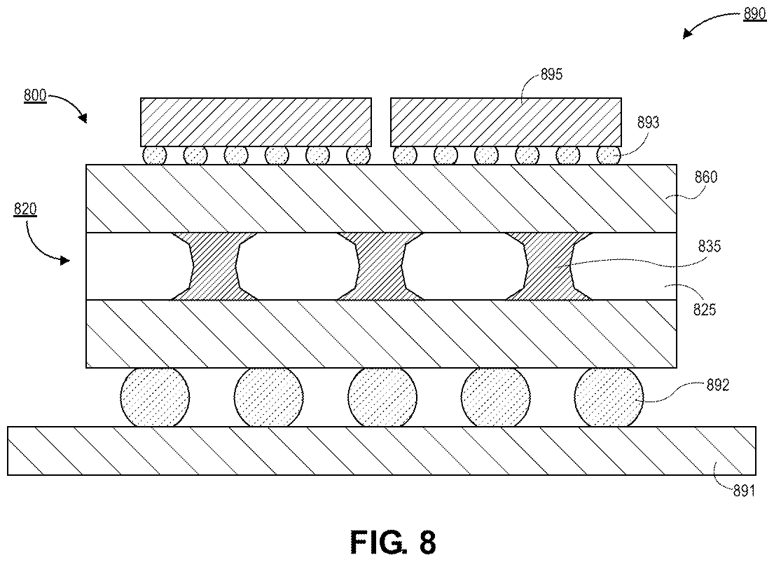

Referring now to FIG. 8, a cross-sectional illustration of an electronic system 890 is shown, in accordance with an embodiment. The electronic system 890 may comprise a board 891, such as a printed circuit board (PCB). The board 891 may be coupled to a package substrate 800 by interconnects 892. The interconnects 892 may be second level interconnect (SLI) architectures, such as solder balls, sockets, or the like.

In an embodiment, the package substrate 800 may be similar to the package substrate 700 described in greater detail above. That is, the package substrate 800 may comprise a glass core 820 with a glass layer 825 and vias 835. The vias 835 may be similar to any of the via architectures described in greater detail herein. The package substrate 800 may comprise buildup layers 860 above and/or below the glass core 820.

In an embodiment, the package substrate 800 may be coupled to one or more dies 895 by interconnects 893. The interconnects 893 may be first level interconnect (FLI) architectures, such as solder balls, copper bumps, hybrid bonding interfaces, or the like. In an embodiment, the dies 895 may include any type of die. For example, the dies 895 may comprise a central processing unit (CPU), a graphics processing unit (GPU), an XPU, a communications die, a memory die, or the like. In some embodiments, two dies 895 may be communicatively coupled together by a bridge that is embedded within the buildup layers 860 or provided above the buildup layers 860.

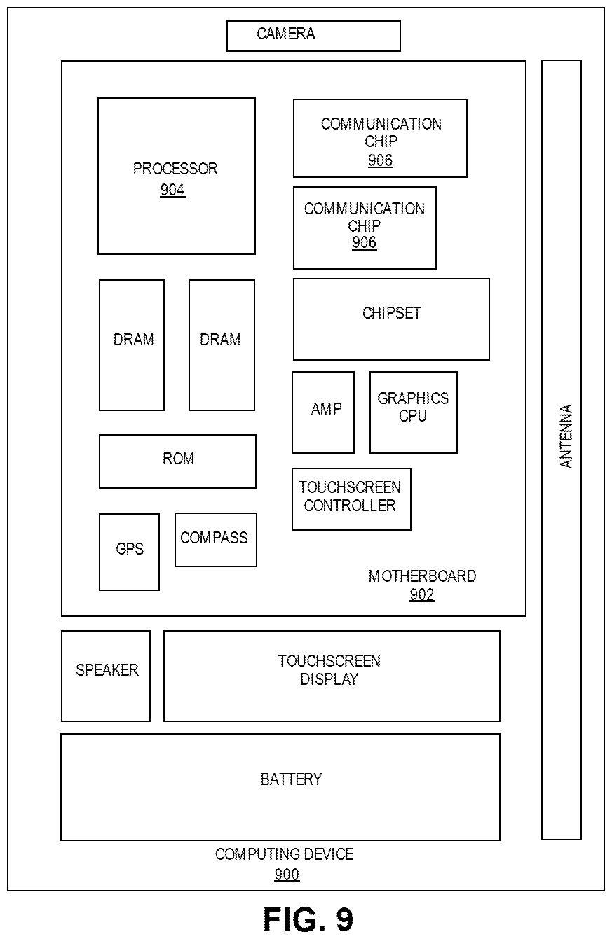

FIG. 9 illustrates a computing device 900 in accordance with one implementation of the disclosure. The computing device 900 houses a board 902. The board 902 may include a number of components, including but not limited to a processor 904 and at least one communication chip 906. The processor 904 is physically and electrically coupled to the board 902. In some implementations the at least one communication chip 906 is also physically and electrically coupled to the board 902. In further implementations, the communication chip 906 is part of the processor 904.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 906 enables wireless communications for the transfer of data to and from the computing device 900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 906 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 900 may include a plurality of communication chips 906. For instance, a first communication chip 906 may be dedicated to shorter range wireless communications such as Wi-Fi and Bluetooth and a second communication chip 906 may be dedicated to longer range wireless communications such as GPS, EDGE, GPRS, CDMA, WiMAX, LTE, Ev-DO, and others.

The processor 904 of the computing device 900 includes an integrated circuit die packaged within the processor 904. In some implementations of the disclosure, the integrated circuit die of the processor may be part of an electronic package that includes a package substrate with a glass core that includes via structures with modulated profiles for maximizing glass core strength, in accordance with embodiments described herein. The term “processor” may refer to any device or portion of a device that processes electronic data from registers and/or memory to transform that electronic data into other electronic data that may be stored in registers and/or memory.

The communication chip 906 also includes an integrated circuit die packaged within the communication chip 906. In accordance with another implementation of the disclosure, the integrated circuit die of the communication chip may be part of an electronic package that includes a package substrate with a glass core that includes via structures with modulated profiles for maximizing glass core strength, in accordance with embodiments described herein.

In an embodiment, the computing device 900 may be part of any apparatus. For example, the computing device may be part of a personal computer, a server, a mobile device, a tablet, an automobile, or the like. That is, the computing device 900 is not limited to being used for any particular type of system, and the computing device 900 may be included in any apparatus that may benefit from computing functionality.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

Example 1: an apparatus, comprising: a substrate with a first surface and a second surface opposite from the first surface, wherein the substrate is a solid glass layer; an opening through a thickness of the substrate, wherein the opening comprises a sidewall that is non-orthogonal with the first surface of the substrate, and wherein a corner at a junction between the sidewall and the first surface is rounded; and a via in the opening, wherein the via is electrically conductive.

Example 2: the apparatus of Example 1, wherein the opening has an hourglass shaped cross-section.

Example 3: the apparatus of Example 1 or Example 2, wherein a second corner at a junction between the sidewall and the second surface is rounded.

Example 4: the apparatus of Examples 1-3, wherein the corner has a radius of curvature of less than approximately 3 μm.

Example 5: the apparatus of Example 4, wherein the radius of curvature is less than approximately 0.5 μm.

Example 6: the apparatus of Examples 1-5, wherein the via has a maximum diameter that is approximately 100 μm or less.

Example 7: the apparatus of Examples 1-6, wherein the via has an aspect ratio (height:width) that is approximately 10:1 or greater.

Example 8: the apparatus of Examples 1-7, wherein the via is voidless.

Example 9: an apparatus, comprising: a substrate, wherein the substrate is a solid glass layer; an opening through a thickness of the substrate, wherein a sidewall of the opening is non-orthogonal to a top surface of the substrate; a liner over the sidewall, wherein a surface of the liner facing away from the sidewall is substantially orthogonal to the top surface of the substrate; and a via in the opening, wherein the via is electrically conductive.

Example 10: the apparatus of Example 9, wherein the liner has a first thickness at a top of the opening and a second thickness at a middle of the opening, wherein the first thickness is greater than the second thickness.

Example 11: the apparatus of Example 9 or Example 10, further comprising: a bump on the sidewall proximate to a top of the opening, and wherein the liner is provided over the bump.

Example 12: the apparatus of Example 11, wherein the bump and the liner are different materials.

Example 13: the apparatus of Examples 9-12, wherein the liner is a polymeric material.

Example 14: the apparatus of Examples 9-13, wherein the opening has an hourglass shaped cross-section.

Example 15: an apparatus, comprising: a substrate, wherein the substrate is a solid glass layer; an opening through a thickness of the substrate, wherein the opening comprises: a first sidewall at a first angle relative to a top surface of the substrate; and a second sidewall at a second angle relative to the top surface of the substrate that is different than the first angle, wherein the first sidewall joins the second sidewall at a corner; and a via in the opening, wherein the via is electrically conductive.

Example 16: the apparatus of Example 15, wherein the first angle is larger than the second angle.

Example 17: the apparatus of Example 15 or Example 16, wherein the opening further comprises: a third sidewall at a third angle relative to the top surface of the substrate, wherein the third angle is a mirror image of the first angle; and a fourth sidewall at a fourth angle relative to the top surface of the substrate, wherein the fourth angle is a mirror image of the second angle.

Example 18: the apparatus of Examples 15-17, wherein the first sidewall is longer than the second sidewall.

Example 19: the apparatus of Examples 15-18, wherein the second sidewall meets the top surface of the substrate at a corner.

Example 20: the apparatus of Examples 15-19, further comprising: a pad over the via, wherein a width of the pad is substantially equal to a maximum width of the via.

What is claimed is:

1. An apparatus, comprising:
a substrate with a first surface and a second surface opposite from the first surface, wherein the substrate is a solid glass layer;
an opening through a thickness of the substrate, wherein the opening comprises a sidewall that is non-orthogonal with the first surface of the substrate, and wherein a corner at a junction between the sidewall and the first surface is rounded; and
a via in the opening, wherein the via is electrically conductive.

2. The apparatus of claim 1, wherein the opening has an hourglass shaped cross-section.

3. The apparatus of claim 1, wherein a second corner at a junction between the sidewall and the second surface is rounded.

4. The apparatus of claim 1, wherein the corner has a radius of curvature of less than approximately 3 μm.

5. The apparatus of claim 4, wherein the radius of curvature is less than approximately 0.5 μm.

6. The apparatus of claim 1, wherein the via has a maximum diameter that is approximately 100 μm or less.

7. The apparatus of claim 1, wherein the via has an aspect ratio (height:width) that is approximately 10:1 or greater.

8. The apparatus of claim 1, wherein the via is voidless.

9. An apparatus, comprising:
a substrate, wherein the substrate is a solid glass layer;
an opening through a thickness of the substrate, wherein a sidewall of the opening is non-orthogonal to a top surface of the substrate;
a liner over the sidewall, wherein a surface of the liner facing away from the sidewall is substantially orthogonal to the top surface of the substrate; and
a via in the opening, wherein the via is electrically conductive.

10. The apparatus of claim 9, wherein the liner has a first thickness at a top of the opening and a second thickness at a middle of the opening, wherein the first thickness is greater than the second thickness.

11. The apparatus of claim 9, further comprising:
a bump on the sidewall proximate to a top of the opening, and wherein the liner is provided over the bump.

12. The apparatus of claim 11, wherein the bump and the liner are different materials.

13. The apparatus of claim 9, wherein the liner is a polymeric material.

14. The apparatus of claim 9, wherein the opening has an hourglass shaped cross-section.

15. An apparatus, comprising:
a substrate, wherein the substrate is a solid glass layer;
an opening through a thickness of the substrate, wherein the opening comprises:
a first sidewall at a first angle relative to a top surface of the substrate; and
a second sidewall at a second angle relative to the top surface of the substrate that is different than the first angle, wherein the first sidewall joins the second sidewall at a corner; and
a via in the opening, wherein the via is electrically conductive.

16. The apparatus of claim 15, wherein the first angle is larger than the second angle.

17. The apparatus of claim 15, wherein the opening further comprises:
a third sidewall at a third angle relative to the top surface of the substrate, wherein the third angle is a mirror image of the first angle; and
a fourth sidewall at a fourth angle relative to the top surface of the substrate, wherein the fourth angle is a mirror image of the second angle.

18. The apparatus of claim 15, wherein the first sidewall is longer than the second sidewall.

19. The apparatus of claim 15, wherein the second sidewall meets the top surface of the substrate at a corner.

20. The apparatus of claim 15, further comprising:
a pad over the via, wherein a width of the pad is substantially equal to a maximum width of the via.
